(19) United States
(12) Patent Application Publication
(10) Pub. No.: US 2023/0286412 A1
(43) Pub. Date: Sep. 14, 2023

(54) CONTROL DEVICE, CONTROL METHOD AND STORAGE MEDIUM

(71) Applicant: HONDA MOTOR CO., LTD., Tokyo (JP)

(72) Inventors: Yuki Tominaga, Wako-shi (JP); Yurika Nishimoto, Wako-shi (JP)

(21) Appl. No.: 18/113,083

(22) Filed: Feb. 23, 2023

(30) Foreign Application Priority Data
Mar. 14, 2022 (JP) 2022-038862

(51) Int. Cl. B60L 58/12

(52) U.S. Cl. CPC B60L 58/12; B60L 2240/549; B60L 2260/44

(57) ABSTRACT

A control device includes a total characteristic value calculation part configured to calculate a total characteristic value showing a total characteristic change of a battery, a local characteristic value estimation part configured to estimate a local characteristic value showing a local characteristic change of the battery, and a current controller configured to control a current flowing to the battery on the basis of a ratio between the total characteristic value and the local characteristic value.

### CROSS-REFERENCE TO RELATED APPLICATION

Priority is claimed on Japanese Patent Application No. 2022-038862, filed Mar. 14, 2022, the content of which is incorporated herein by reference.

### BACKGROUND OF THE INVENTION

### Field of the Invention

The present invention relates to a control device, a control method and a storage medium.

### Description of Related Art

When a magnitude of current passing through a battery is great, reaction current is concentrated on an electrode surface of the battery. Here, for example, in the case of a lithium battery, an amount of lithium ions entering and leaving the electrode surface is increased. The amount of lithium ions entering and leaving the electrode surface is greater than the amount of lithium ions entering and leaving the electrodes of the entire battery, and there is a possibility that local deterioration on the electrode surface may progress (Japanese Unexamined Patent Application, First Publication No. 2021-125423, Japanese Unexamined Patent Application, First Publication No. 2020-35531, and Japanese Unexamined Patent Application, First Publication No. 2019-50094).

### SUMMARY OF THE INVENTION

One of purposes of an aspect of the present invention is directed to improving uniformity in deterioration of a battery. Further, it is possible to reduce an adverse influence on the global environment by improving the uniformity in deterioration of batteries.

A control device, a control method and a storage medium according to the present invention employ the following configurations.
(1) A control device according to an aspect of the present invention is a control device including: a total characteristic value calculation part configured to calculate a total characteristic value showing a total characteristic change of a battery; a local characteristic value estimation part configured to estimate a local characteristic value showing a local characteristic change of the battery; and a current controller configured to control a current flowing to the battery on the basis of a ratio between the total characteristic value and the local characteristic value.
(2) In the aspect of the above-mentioned (1), the total characteristic value may be an amount of change of an SOC of the battery, and the local characteristic value may be an amount of change of an SOC due to conduction to a local portion of the battery. (3) In the aspect of the above-mentioned (1), the total characteristic value is an integrated value of a current flowing through the entire battery, and the local characteristic value is an integrated value of a current flowing to a local portion of the battery.
(4) In the aspect of any one of the above-mentioned (1) to (3), the local characteristic value estimation part calculates an equivalent circuit on the basis of a measurement result of impedance of the battery, and estimates the local characteristic value on the basis of the total characteristic value and the equivalent circuit.
(5) A control method according to an aspect of the present invention is a control method of causing a computer to: calculate a total characteristic value showing a total characteristic change of a battery; estimate a local characteristic value showing a local characteristic change of the battery; and control a current flowing to the battery on the basis of a ratio between the total characteristic value and the local characteristic value.
(6) A storage medium according to an aspect of the present invention is a computer-readable non-transient storage medium on which a program is stored, the program causing a computer to: calculate a total characteristic value showing a total characteristic change of a battery; estimate a local characteristic value showing a local characteristic change of the battery; and control a current flowing to the battery on the basis of a ratio between the total characteristic value and the local characteristic value.

According to the aspects of the above-mentioned (1) to (6), it is possible to improve uniformity of deterioration of the battery by controlling the current flowing to the battery based on the local characteristic value.

### BRIEF DESCRIPTION OF THE DRAWINGS

FIG. 1 is a view showing an example of a configuration of a vehicle according to an embodiment.

FIG. 2 is a view showing a configuration of a controller according to the embodiment.

FIG. 3 is a view showing an equivalent circuit stored in an equivalent circuit storage according to the embodiment.

FIG. 4 is an example of a Cole-Cole plot.

FIG. 5 is a flowchart showing an operation of the controller according to the embodiment.

### DETAILED DESCRIPTION OF THE INVENTION

Hereinafter, embodiments of a control device, a control method and a storage medium of the present invention will be described with reference to the accompanying drawings.

### [Configuration of Vehicle]

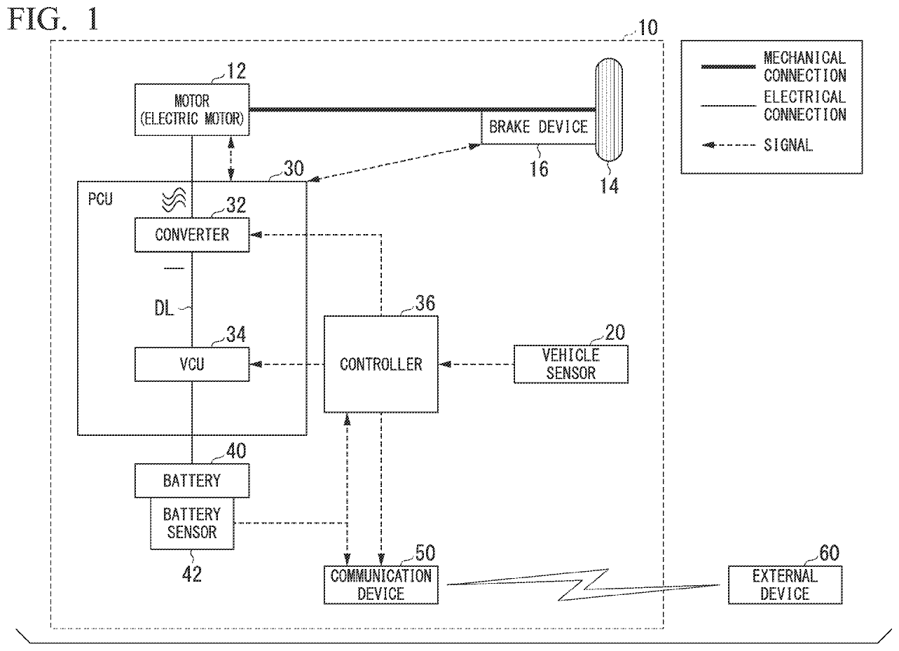

FIG. 1 is a view showing an example of a configuration of a vehicle 10 according to the embodiment. The vehicle 10 shown in FIG. 1 is a battery electric vehicle (BEV: electric automobile) that travels using an electric motor driven by electric power supplied from a battery for traveling (secondary battery). Alternatively, the vehicle 10 may be a plug-in hybrid vehicle (PHV) or a plug-in hybrid electric vehicle (PHEV) having an external charging function on a hybrid vehicle. Further, the vehicle 10 may be, for example, not only a four-wheeled vehicle but also a saddle riding type two-wheeled vehicle, a vehicle such as a three-wheeled vehicle (including a two-front-wheeled and one-rear-wheeled vehicle in addition to a one-front-wheeled and two-rear-wheeled vehicle), an assisted bicycle, an electric boat, or the like, and all moving bodies that travel using an electric motor driven by electric power supplied from a battery.

A motor 12 is, for example, a three-phase alternating current motor. A rotator (rotor) of the motor 12 is connected to a driving wheel 14. The motor 12 is driven by electric power supplied from a power accumulation part (not shown) provided in a battery 40, and rotational power is transferred to the driving wheel 14. In addition, the motor 12 generates power using kinetic energy of the vehicle 10 upon deceleration of the vehicle 10.

A brake device 16 includes, for example, a brake caliper, a cylinder configured to transmit a hydraulic pressure to a brake caliper, and an electric motor configured to generate a hydraulic pressure in the cylinder. The brake device 16 may include a mechanism configured to transmit a hydraulic pressure generated by an operation by a user (driver) of the vehicle 10 with respect to a brake pedal (not shown) to the cylinder via a master cylinder as a backup. Further, the brake device 16 is not limited to the above-mentioned configuration and may be an electrically-controlled hydraulic brake device configured to transmit a hydraulic pressure of a master cylinder to a cylinder.

A vehicle sensor 20 includes, for example, an accelerator position sensor, a vehicle speed sensor, and a brake pedaling sensor. The accelerator position sensor is attached to the accelerator pedal, detects an operation amount of the accelerator pedal by a driver, and outputs the detected operation amount to a controller 36, which will be described below, as an accelerator open degree. The vehicle speed sensor includes, for example, wheel speed sensors attached to each of the wheels of the vehicle 10, and a speed calculator, derives a speed of the vehicle 10 (vehicle speed) by integrating wheel speeds detected by the wheel speed sensors, and outputs the speed to the controller 36. The brake pedaling sensor is attached to a brake pedal, detects an operation amount of the brake pedal by a driver, and outputs the detected operation amount to the controller 36 as an amount of brake depression.

A PCU 30 includes, for example, a converter 32 and a voltage control unit (VCU) 34. Further, in FIG. 1, it is only an example that these components are collectively configured as the PCU 30, and these components in the vehicle 10 may be disposed in a distributed manner.

The converter 32 is, for example, an AC-DC converter. A direct current-side terminal of the converter 32 is connected to a direct current link DL. The battery 40 is connected to the direct current link DL via the VCU 34. The converter 32 converts alternating current generated by the motor 12 into direct current, and outputs the direct current to the direct current link DL.

The VCU 34 is, for example, a DC-DC converter. The VCU 34 boosts the electric power supplied from the battery 40 and outputs the boosted electric power to the direct current link DL.

The controller 36 controls driving of the motor 12 on the basis of the output from the accelerator position sensor provided in the vehicle sensor 20. The controller 36 controls the brake device 16 on the basis of the output from the brake pedaling sensor provided in the vehicle sensor 20. The controller 36 controls the VCU 34 and controls current flowing to the battery 40 on the basis of an output from a battery sensor 42, which will be described below, connected to the battery 40. A configuration of the controller 36 will be described below in detail.

The battery 40 is a secondary battery such as a lithium ion battery or the like that is capable of repeating charge and discharge. A positive electrode active material that constitutes the positive electrode of the battery 40 is a material containing at least one of materials such as nickel cobalt manganese (NCM), nickel cobalt aluminum (NCA), lithium ferrophosphate (LFP), lithium manganese oxide (LMO), and the like, and a negative electrode active material that constitutes the negative electrode of the battery 40 is a material containing at least one of materials such as hard carbon, graphite, and the like. In addition, the battery 40 may be, for example, a cassette type battery pack or the like, which is detachably attached to the vehicle 10. The battery 40 stores electric power supplied from an external charger (not shown) of the vehicle 10 and discharges the electric power for traveling of the vehicle 10.

The battery sensor 42 detects a physical quantity such as a current, a voltage, a temperature, or the like, of the battery 40. The battery sensor 42 includes, for example, a current sensor, a voltage sensor, and a temperature sensor. The battery sensor 42 detects a current of a secondary battery that constitutes the battery 40 (hereinafter, simply referred to as “the battery 40”) using a current sensor, detects a voltage of the battery 40 using a voltage sensor, and detects a temperature of the battery 40 using a temperature sensor. The battery sensor 42 outputs data of the detected physical quantity such as the current value, the voltage value, the temperature, or the like, of the battery 40 to the controller 36 and/or a communication device 50.

The communication device 50 includes a wireless module configured to connect a cellular network or a Wi-Fi network. The communication device 50 may include a wireless module configured to use Bluetooth (registered trademark) or the like. The communication device 50 transmits and receives various types of information related to the vehicle 10 to/from, for example, an external device 60 through communication in the wireless module. The communication device 50 transmits data of the physical quantity of the battery 40 output by the controller 36 or the battery sensor 42 to the external device 60.

### [Configuration of Controller]

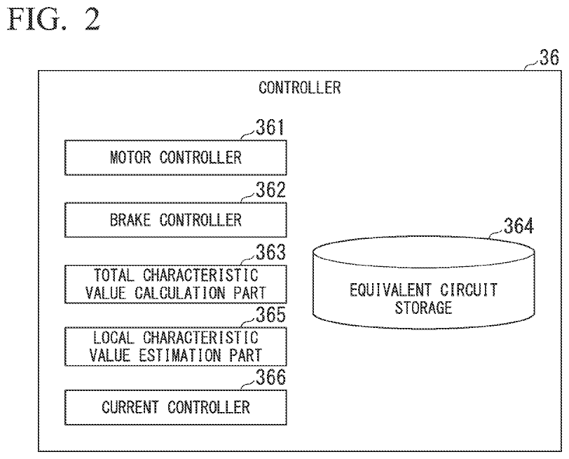

FIG. 2 is a view showing a configuration of the controller 36 according to the embodiment. The controller 36 includes a motor controller 361, a brake controller 362, a total characteristic value calculation part 363, an equivalent circuit storage 364, a local characteristic value estimation part 365 and a current controller 366. These components are realized by executing a program (software) using a hardware processor such as a central processing unit (CPU) or the like. Some or all of these components may be realized by hardware (circuit part; including circuitry) such as large scale integration (LSI), an application specific integrated circuit (ASIC), a field-programmable gate array (FPGA), a graphics processing unit (GPU), or the like, or may be realized by cooperation of software and hardware. The program may be stored in a storage device (a storage device including a non-transient storage medium) such as a hard disk drive (HDD), a flash memory, or the like, in advance, may be stored in a detachable storage medium (non-transient storage medium) such as a DVD, a CD-ROM, or the like, or may be installed by mounting the storage medium in a drive device.

The motor controller 361 controls driving of the motor 12 on the basis of the output from the accelerator position sensor provided in the vehicle sensor 20. The brake controller 362 controls the brake device 16 on the basis of the output from the brake pedaling sensor provided in the vehicle sensor 20.

The total characteristic value calculation part 363 calculates a total characteristic value of the battery 40 on the basis of the detection result by the battery sensor 42. The total characteristic value of the battery 40 is a value showing the total characteristic change of the battery 40, and for example, an amount of change in a state of charge of the battery 40 (SOC; also referred to as “a battery charge rate”), or an integrated value of the current flowing through the battery 40. The total characteristic value may be an amount of change of the entire SOC of the electrode plate of the battery 40 or an average value of the integrated values of the flowing current.

The equivalent circuit storage 364 stores an equivalent circuit showing the battery 40. The equivalent circuit is data drafted before the local characteristic value estimation part 365 is estimated, which will be described below, and recorded on the equivalent circuit storage 364. Hereinafter, a method of drafting the equivalent circuit will be described.

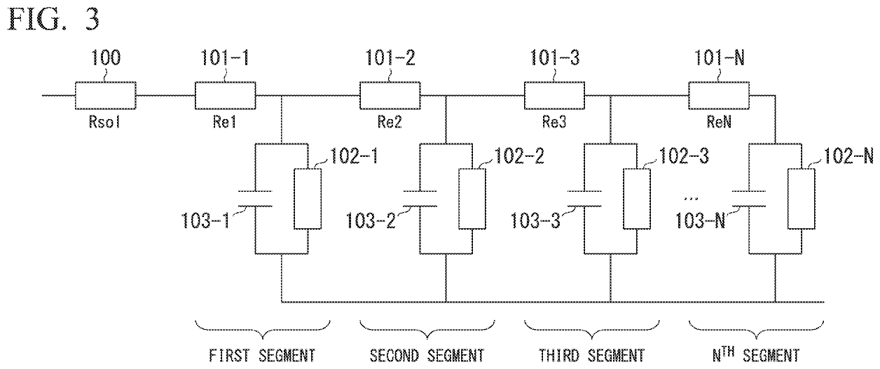

FIG. 3 is a view showing the equivalent circuit stored in the equivalent circuit storage 364 according to the embodiment. The equivalent circuit is constituted by N segments consisting of a resistor 100, a resistor 101, a resistor 102 and a capacitor 103. In the equivalent circuit, a side where the resistor 100 is provided is a side of the electrode current collecting foil, and an opposite side is a side of the electrode surface. In each segment, the resistor 102 and the capacitor 103 are connected in parallel (hereinafter, the circuit is referred to as a parallel circuit 104). In each segment, the parallel circuit 104 and the resistor 101 are connected in series. Between the adjacent segments, the resistor 101 on the side of the electrode surface is connected between the resistor 101 on the side of the electrode current collecting foil and the parallel circuit 104. In addition, between the adjacent segments, the parallel circuit 104 is connected to the resistor 101 at a side opposite to the connected side. The number of segments N is a number assumed as the number of layers of the active material on the electrode of the battery 40.

First, a resistance value and a capacitance of an element that constitutes the equivalent circuit when the segment is one are calculated. For example, they are calculated by setting the resistance value and the capacitance of the equivalent circuit to be fitted to a Cole-Cole plot of impedance measured from the battery 40.

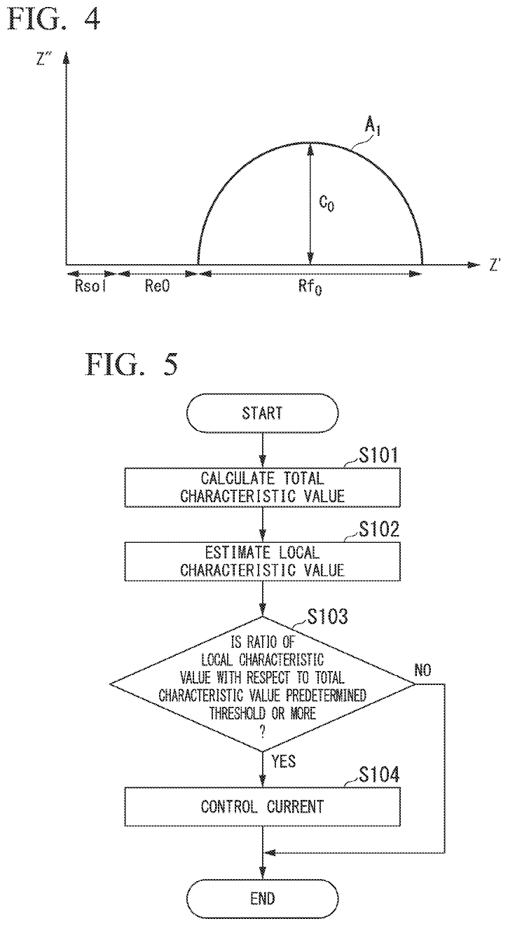

FIG. 4 is an example of the Cole-Cole plot. FIG. 4 shows a Cole-Cole plot when a resistance value of the resistor 100 is set as Rso1, a resistance value of the resistor 101 of the segment is set as Re0, a resistance value of the resistor 102 is set as Rf0, and a capacitance of the capacitor 103 is set as C0. An oval A₁ is observed in the Cole-Cole plot. A length of the oval A₁ in a longitudinal direction is C0, and a length in a lateral direction is Rf0. In addition, a sum of Rso1 and Re0 is a lateral axis ingredient of a left end point of the oval A₁. Accordingly, Rso1, Re0, Rf0, and C0 can be calculated.

Next, the equivalent circuit when the N segments are provided is calculated from the equivalent circuit when a single segment is provided. A resistance value of a resistor 101-k of a k^{th} segment is set as Rek, a resistance value of a resistor 102-k is set as Rfk, and a capacitance of a capacitor 103-k is set as Ck. Here, Rek is a value obtained by dividing Re0 by N, Rfk is a value obtained by multiplying Rf0 by N, and Ck is a value obtained by dividing C0 by N. As described above, the resistance value and the capacitance of the element that constitutes the equivalent circuit consisting of the resistor 100 and the N segments shown in FIG. 3 are calculated.

The local characteristic value estimation part 365 estimates a local characteristic value of the battery 40 on the basis of the equivalent circuit recorded on the equivalent circuit storage 364 and the total characteristic value of the battery 40. The local characteristic value of the battery 40 is a value showing a local characteristic change of the battery 40 and is, for example, an amount of change of the SOC due to conduction to the local portion of the battery 40 or an integrated value of the current flowing through the local portion of the battery 40. The local portion of the battery 40 is the side of the electrode current collecting foil of the electrode plate of the battery 40, and the current flowing through the local portion in the equivalent circuit is a current flowing through the resistor 102 of each of the segments.

The local characteristic value estimation part 365 estimates the current flowing through the resistor 102-1 of the first segment as the local characteristic value, for example, when the current flowing through the entire battery 40 flows through the resistor 100 of the equivalent circuit. A magnitude of the current flowing through the resistor 102-1 of the first segment depends on a time length after the current starts to flow through the resistor 100 and is calculated as a function of time. In addition, like the current flowing through the resistor 102-1 of the first segment, a current flowing through the resistor 102-k of the k* segment can also be calculated.

The current controller 366 controls the VCU 34 on the basis of the total characteristic value and the local characteristic value of the battery 40, and controls the current flowing through the battery 40. For example, the current controller 366 determines whether a ratio of the local characteristic value with respect to the total characteristic value exceeds a predetermined threshold. When the ratio of the local characteristic value with respect to the total characteristic value exceeds the predetermined threshold, the current controller 366 controls the VCU 34 and controls the current flowing to the battery 40. The predetermined threshold is, for example, a previously set value.

FIG. 5 is a flowchart showing an operation of the controller 36 according to the embodiment. In the example of FIG. 5, the total characteristic value calculation part 363 calculates the total characteristic value of the battery 40 on the basis of the detection result by the battery sensor 42 (step S101). Next, the local characteristic value estimation part 365 estimates the local characteristic value of the battery 40 on the basis of the equivalent circuit stored on the equivalent circuit storage 364 and the total characteristic value of the battery 40 (step S102). Next, the current controller 366 determines whether the ratio of the local characteristic value with respect to the total characteristic value exceeds the predetermined threshold (step S103). When the ratio of the local characteristic value with respect to the total characteristic value exceeds the predetermined threshold, the current controller 366 controls the VCU 34 and controls the current flowing to the battery 40 (step S104). Accordingly, processing of the flowchart is terminated.

According to the embodiment as described above, since the controller 36 provided in the vehicle 10 includes the total characteristic value calculation part 363 configured to calculate the total characteristic value showing the total characteristic change of the battery 40, the local characteristic value estimation part 365 configured to estimate the local characteristic value showing the local characteristic change of the battery 40, and the current controller 366 configured to control the current flowing to the battery 40 on the basis of the ratio between the total characteristic value and the local characteristic value, it is possible to suppress the current from flowing to the battery 40 according to the change of the local characteristic value and improve uniformity of deterioration of the battery 40.

Further, some or all of the total characteristic value calculation part 363, the equivalent circuit storage 364, the local characteristic value estimation part 365 and the current controller 366 that constitute a part of the controller 36 may be provided in the external device 60.

The above-mentioned embodiment can be expressed as follows.

A control device includes:
a storage device on which a program is stored; and
a hardwire processor, and
the control device is configured to calculate a total characteristic value showing a total characteristic change of a battery,
estimates a local characteristic value showing a local characteristic change of the battery, and
controls a current flowing to the battery on the basis of a ratio between the total characteristic value and the local characteristic value,
when the hardwire processor executes the program stored on the storage device.

While preferred embodiments of the invention have been described and illustrated above, it should be understood that these are exemplary of the invention and are not to be considered as limiting. Additions, omissions, substitutions, and other modifications can be made without departing from the scope of the present invention. Accordingly, the invention is not to be considered as being limited by the foregoing description, and is only limited by the scope of the appended claims.

What is claimed is:

1. A control device comprising:
a total characteristic value calculation part configured to calculate a total characteristic value showing a total characteristic change of a battery;
a local characteristic value estimation part configured to estimate a local characteristic value showing a local characteristic change of the battery; and
a current controller configured to control a current flowing to the battery on the basis of a ratio between the total characteristic value and the local characteristic value.

2. The control device according to claim 1, wherein the total characteristic value is an amount of change of an SOC of the battery, and
the local characteristic value is an amount of change of an SOC due to conduction to a local portion of the battery.

3. The control device according to claim 1, wherein the total characteristic value is an integrated value of a current flowing through the entire battery, and
the local characteristic value is an integrated value of a current flowing to a local portion of the battery.

4. The control device according to claim 1, wherein the local characteristic value estimation part calculates an equivalent circuit on the basis of a measurement result of impedance of the battery, and estimates the local characteristic value on the basis of the total characteristic value and the equivalent circuit.

5. A control method of causing a computer to:
calculate a total characteristic value showing a total characteristic change of a battery;
estimate a local characteristic value showing a local characteristic change of the battery; and
control a current flowing to the battery on the basis of a ratio between the total characteristic value and the local characteristic value.

6. A computer-readable non-transient storage medium on which a program is stored, the program causing a computer to:
calculate a total characteristic value showing a total characteristic change of a battery;
estimate a local characteristic value showing a local characteristic change of the battery; and
control a current flowing to the battery on the basis of a ratio between the total characteristic value and the local characteristic value.
